(19) United States
(12) Patent Application Publication
(10) Pub. No.: US 2026/0313845 A1
(43) Pub. Date: Oct. 8, 2026

(54) METHOD FOR OPERATING A COOLING DEVICE IN THE EVENT OF A LEAKAGE AND A CORRESPONDING COOLING DEVICE

(71) Applicant: RITTAL GMBH & CO. KG, Herborn (DE)

(72) Inventors: Thorsten HEIMBERG, Schöffengrund (DE); Lena Kristin CORNELIUS, Leun (DE); Jörg KNETSCH, Ehringshausen (DE); Juan Carlos CACHO ALONSO, Braunschweig (DE); Lars Walter NIEBERGALL, Wetzlar (DE)

(21) Appl. No.: 18/880,748

(22) PCT Filed: Jun. 19, 2023
(86) PCT No.: PCT/DE2023/100455

§ 371 Date: Jan. 2, 2025

(30) Foreign Application Priority Data
Jul. 12, 2022 (DE) 10 2022 117 366.6

(51) Int. Cl. H05K 7/20; G01M 3/04; H02B 1/56

(52) U.S. Cl. CPC H05K 7/20381; G01M 3/04; H02B 1/565; H05K 7/20354; H05K 7/20827; H05K 7/20836

(57) ABSTRACT

A method for operating a cooling device for the switchgear cabinet air conditioning or the air conditioning of an IT environment, in particular a data centre, which comprises the steps:
A. operating a refrigerating machine of the cooling device, the refrigerating machine comprising a refrigerant circuit with a compressor, a condenser, an expansion member and an evaporator;
B. detecting a leakage of the refrigerant circuit, in which refrigerant escapes from the refrigerant circuit;
C. shutting off a feed of the evaporator between the evaporator and the condenser; and
D. activating and/or maintaining the compressor activated.
   Furthermore, a corresponding cooling device is described.

### CROSS-REFERENCE TO RELATED APPLICATIONS

This application is a U.S. National Phase Application under 35 U.S.C. 371 of International Application No. PCT/DE 2023/100455, filed on Jun. 19, 2023, which claims priority to German Patent Application No. 10 2022 117 366.6, filed on Jul. 12, 2022. The entire disclosures of the above applications are incorporated herein by reference.

### BACKGROUND

This section provides background information related to the present disclosure which is not necessarily prior art.

### Technical Field

The invention is based on a method for operating a cooling device for the switchgear cabinet air conditioning or the air conditioning of an IT environment, for example a data center, which comprises the operation of a refrigerating machine of the cooling device, wherein the refrigerating machine comprises a refrigerant circuit with a compressor, a condenser, an expansion member and an evaporator. The method furthermore comprises the detection of a leakage of the refrigerant circuit, wherein refrigerant escapes from the refrigerant circuit. Such a method and a corresponding cooling device are known from DE 10 2018 109 604 A1.

### Discussion

The Directive 2006/42/EC (Machine Directive) requires that there is no risk of explosion and fire from gases used in a machine, wherein it is to be assumed that individual components fail. If, therefore, in a switchgear cabinet cooling device, a refrigerant-carrying part has an assumed leakage, it is to be assumed that combustible gas (refrigerant) passes into the switchgear cabinet and can ignite there on internal components which ignite arcs during operation. Without a safety function which reliably prevents this, switchgear cabinet cooling devices which use combustible refrigerants cannot meet the machine directive or be operated with the required safety for the end user.

The cooling devices known from the prior art for the switchgear cabinet air conditioning have the disadvantage that they are comparatively complex to implement, since, for example, different, actively driven closing members are required in order, in the event of a detected leakage and in the event of entry of a combustible refrigerant into the interior of the switchgear cabinet, to fluidically separate the internal air circuit of the cooling device from the switchgear cabinet atmosphere in the interior of the switchgear cabinet housing.

### SUMMARY

This section provides a general summary of the disclosure and is not a comprehensive disclosure of its full scope or all of its features.

It is therefore one aspect of the invention to propose a method for operating a cooling device in the event of a leakage and a corresponding cooling device which are implemented with simple technical means and are accordingly inexpensive to provide.

Accordingly, it is provided that, in the method, a feed of the evaporator between the evaporator and the condenser is shut off and the compressor is kept activated and/or maintained activated. The invention is based on the knowledge that, in the internal air circuit of the cooling device, that is to say in that region of the cooling device which is open to the switchgear cabinet atmosphere or to the atmosphere of the IT environment, for example a data center, the evaporator is particularly susceptible to leakage.

If the evaporator or a pipeline system of the evaporator which is connected to the refrigerant circuit is brought to a negative pressure with respect to the atmosphere in the interior of the switchgear cabinet housing or of the IT environment, or the internal pressure in the pipeline system is further adjusted to the atmospheric pressure, the uncontrolled escape of refrigerant, which could lead to the critical enrichment of the refrigerant, can be prevented particularly effectively.

The evaporator can be configured, for example, as an air-liquid heat exchanger. The air-liquid heat exchanger can comprise a fin pack which is penetrated by the air flowing through the evaporator. The fin pack can be penetrated by a pipeline system connected to the refrigerant circuit, in order to achieve the heat exchange between the air flowing through the evaporator and the refrigerant flowing through the line system. For example, the pipeline system penetrating the evaporator, in particular the fin pack, can comprise a plurality of straight pipeline sections which run parallel to one another and which are connected to one another at opposite end sides of the evaporator via pipe bends, in particular 180° pipe bends. The connecting points can be configured, in particular, as joining points, for example as soldering points, which are susceptible to leakage. The pipe bends themselves are also more susceptible to leakage than the straight pipe section.

The method according to the invention can accordingly be configured to empty, in the event of a leakage, in particular the evaporator and preferably also the other components of the refrigerant circuit arranged in the internal air circuit from the refrigerant.

It can therefore be provided that the activation and/or maintaining the compressor activated comprises the emptying of the refrigerant circuit at least in a line section of the refrigerant circuit which is arranged in an internal air circuit of the refrigeration appliance.

Refrigerant which is emptied from the line section of the refrigerant circuit arranged in the internal air circuit can be transferred into a line section of the refrigerant circuit arranged in the external air circuit.

The transfer of the refrigerant into a line section arranged in the external air circuit can comprise the introduction of the refrigerant into a buffer store, preferably into an air-liquid heat exchanger of the condenser, particularly preferably into a line system of the air-liquid heat exchanger, with which the refrigerant is guided through the air-liquid heat exchanger in thermal contact with a plurality of fins of the air-liquid heat exchanger.

For shutting off the feed of the evaporator, the expansion member can be transferred into a closed position which is completely impermeable or substantially impermeable to the refrigerant. Accordingly, no further shut-off member is required, and therefore the method can be carried out with cooling devices known from the prior art without structural reconfiguration.

The activation and/or maintaining the compressor activated can comprise the raising of the rotational speed of the compressor, wherein the compressor is preferably operated at a maximum rotational speed.

The shutting off of the feed of the evaporator between the evaporator and the condenser can comprise the shutting off of a line section of the refrigerant circuit which is arranged in an external air circuit of the refrigeration appliance.

During the activation and/or maintaining the compressor activated, the compressor can be kept activated either for a predetermined minimum duration and/or until a section of the refrigerant circuit, including the evaporator, arranged in the internal air circuit of the refrigeration appliance is completely or substantially completely emptied of the refrigerant.

After the activation and/or maintaining the compressor activated, the method can comprise the shutting off of a suction line of the compressor, via which suction line the compressor is connected to a return of the evaporator, and optionally the deactivation of the compressor. The deactivation preferably takes place after the shutting off of the suction line.

According to another aspect, a cooling device for the switchgear cabinet air conditioning or the air conditioning of an IT environment, in particular a data center, is described. The cooling device accordingly comprises a refrigerating machine with a refrigerant circuit, wherein the refrigerant circuit comprises a compressor, a condenser, an expansion member and an evaporator. A feed of the evaporator comprises a shut-off member between the evaporator and the condenser, which shut-off member is configured to completely close the feed in the event of a leakage of the refrigerant circuit. The cooling device is not restricted to any specific structural forms and can be, for example, a compact cooling device for the hanging mounting on a switchgear cabinet housing, a slide-in cooling device for the integration into a switchgear cabinet row, a split device or the like.

The shut-off member can be the expansion member of the refrigerant circuit. An additional shut-off member for carrying out the method according to the invention would therefore not be required.

The shut-off member can be motor-driven. It can be controlled by a control unit which comprises a signal input for a refrigerant sensor. The refrigerant sensor can be arranged in or on the cooling device or can be positioned independently of the cooling device. For example, the refrigerant sensor can be arranged on an outer side of the cooling device facing a switch cabinet interior or an IT environment, for example in a data centre. The refrigerant sensor can be arranged for example in an air inlet opening or an air outlet opening of an internal air circuit of the cooling device or in the internal air circuit of the cooling device. The refrigerant sensor can be connected wirelessly or by wire to the signal input of the control unit for the signal transmission.

The cooling device can comprise a further, preferably motor-driven shut-off member in a suction line of the compressor. The further shut-off member can serve, after emptying of at least the evaporator or a section of the refrigerant circuit arranged in the internal air circuit has taken place, to fluidically separate the section of the refrigerant circuit arranged in the internal air circuit with its components integrated therein, for example the evaporator, from the part of the refrigerant circuit arranged in the external air circuit, wherein the refrigerant is held in the part of the refrigerant circuit arranged in the external air circuit.

At least the condenser, the compressor and at least one fan for acting on the condenser with air can be accommodated separately from the evaporator in a separate housing which is connected via two pipeline sections to the feed and the return of the evaporator. The cooling device can be configured as a so-called split device with housings which are connected to one another via the two pipeline sections, but are separate.

The pipeline section connected to the feed of the evaporator can comprise the shut-off member. In this case, the shut-off member can preferably be arranged closer to the evaporator than to the condenser along the pipeline section. As a result, it is achieved that, in the event of a leakage, the pipeline sections can be used as a buffer store for the refrigerant which is emptied from the evaporator.

The pipeline section connected to the return of the evaporator and the suction line of the compressor can comprise a further shut-off member. The further shut-off member can be arranged closer to the evaporator than to the compressor along the pipeline section. In this case, too, the pipeline section can in turn serve as a buffer store for refrigerant in the event of a leakage.

The compressor, the condenser, the expansion member, the evaporator and the at least one shut-off member can be connected to one another via a pipeline system of the refrigerant circuit. The pipeline system can be conditioned with respect to its volume, in particular at least one of the pipeline cross-section and the pipeline length, such that the pipeline system is a buffer store for refrigerant compressed by the compressor in the event of a leakage when the feed of the evaporator is shut off.

The compressor can be arranged in the internal air circuit, preferably in a housing in which at least the evaporator and the compressor are arranged. In this case, the housing can preferably be formed independently of a further housing in which the condenser and the external air circuit are arranged. The housing can be arranged with the internal air circuit in an IT environment, for instance in a data center, and the further housing can be arranged with the external air circuit outside the IT environment.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

Further details of the invention will be explained with reference to the figures below. In the figures:

FIG. 1 shows an exemplary embodiment of a switchgear cabinet arrangement with a cooling device according to the invention; and

FIG. 2 shows an exemplary embodiment of an IT environment with a further embodiment of a cooling device according to the invention.

### DETAILED DESCRIPTION

Example embodiments will now be described more fully with reference to the accompanying drawings.

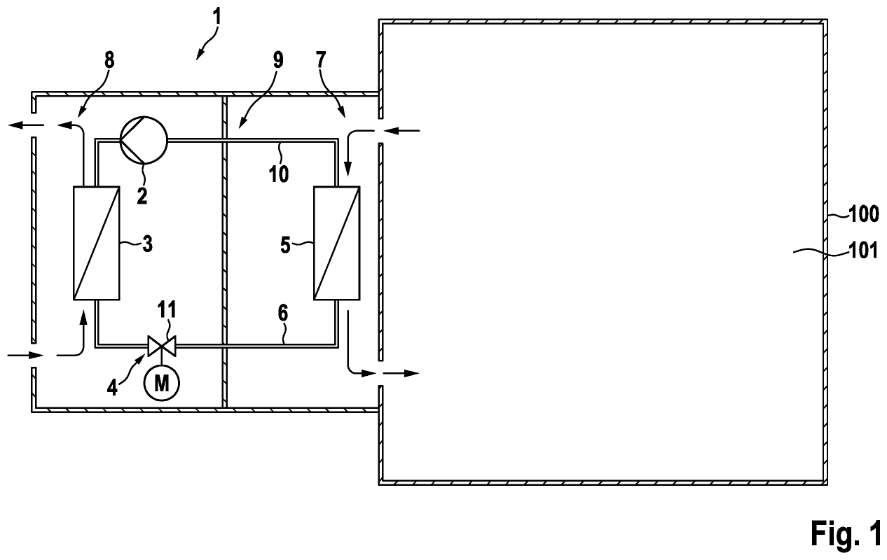

The embodiment according to FIG. 1 substantially comprises a switchgear cabinet housing 100 on which a cooling device 1 is mounted, for example, in a suspended manner. The cooling device 1 comprises, on a vertical side wall, in an upper region, an air inlet in the internal air circuit 7 for warm air and, in a lower region, an air outlet from the internal air circuit 7 for cooled air. Heat-emitting components (not illustrated) which are acted on by air cooled with the aid of the cooling device 100 can be arranged in the interior 101 of the switchgear cabinet 100. The components in the interior 101 can generate arcs during operation, on which, in the event of a leakage, a refrigerant which emerges from the cooling device 1 and which forms a stoichiometric mixture in the atmosphere of the interior 101 with the air in the interior 101 could ignite.

The cooling device 1 accordingly comprises an internal air circuit 7 through which the air received in the switch cabinet interior 101 is conducted and in the process passes an evaporator 5, as a result of which the air cools. An external air circuit 8 through which ambient air is conducted is fluidically separated from the internal air circuit 7. In a lower region of the external air circuit 8, ambient air is introduced into the external air circuit 8. The ambient air acts on the condenser 3 and leaves the external air circuit 8 as heated air in an upper region of the cooling device 1. Furthermore, a compressor 3 and an expansion member 4 are arranged in the external air circuit 8.

In the embodiment shown in FIG. 1, the expansion member 4 furthermore has the function of a shut-off member 11. The function of a shut-off member 11 is required for carrying out the method according to the invention. Accordingly, in the event of a detected leakage of the refrigerant circuit, the cooling device can be operated such that the refrigerant received in the refrigerant circuit is concentrated in the region of the refrigerant circuit arranged in the external air circuit 8 and, in particular, the evaporator which is arranged in the internal air circuit and is particularly susceptible to leakage is emptied or substantially emptied.

For the detection of the leakage, a refrigerant sensor can be arranged in the internal air circuit 7 or in the interior 101. According to the method according to the invention, it is now provided that, in the event of a leakage, the feed 6 of the evaporator 5 between the evaporator 5 and the condenser 3 is shut off. Furthermore, the compressor 2 is activated when it is not already in an active state. When the compressor 2 is already in an active state, it is kept in the active state in order to achieve as complete emptying as possible of the evaporator 5 and of the other pipeline sections of the refrigerant circuit arranged in the internal air circuit 7.

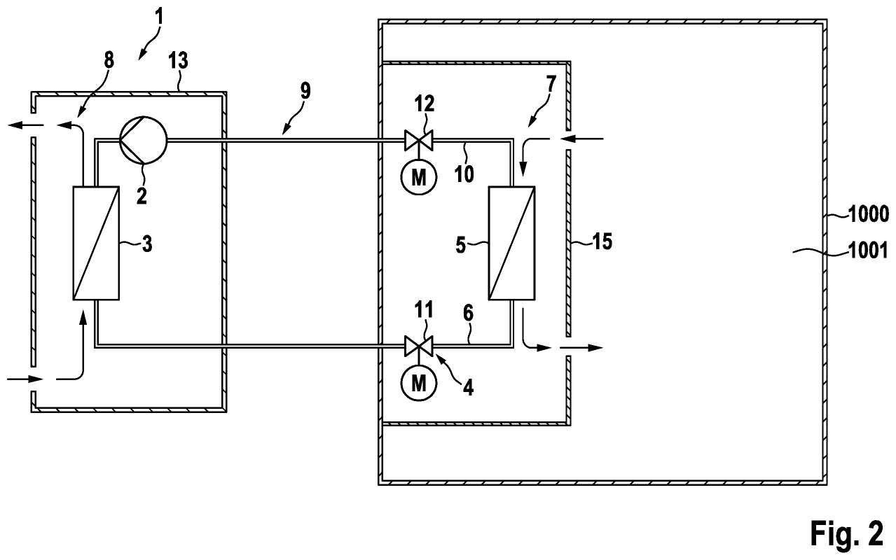

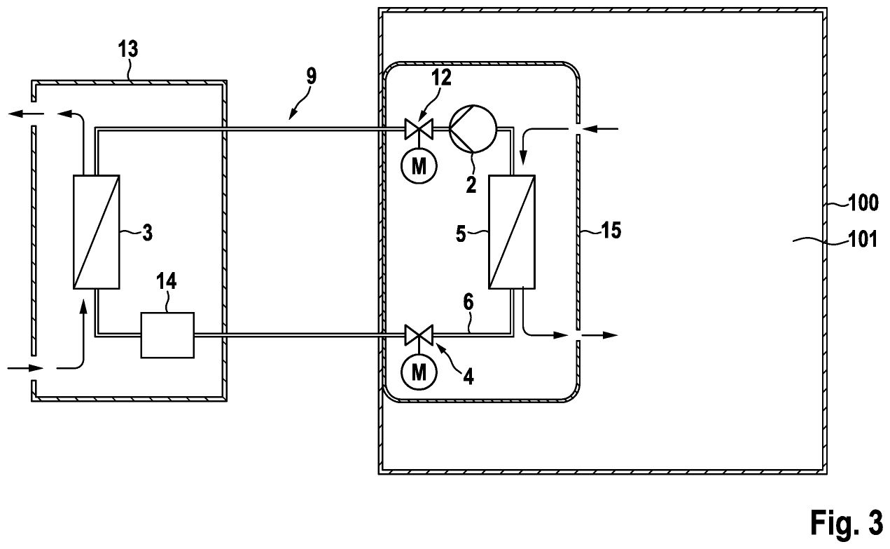

Deviating from the embodiment illustrated in FIG. 1, in the embodiment illustrated in FIG. 2, the cooling device 1 is configured as a split device in which at least the condenser 3 and the evaporator 2 with the external air circuit 8 are arranged in a housing 13 which is separate from the other components of the cooling device 1. The housing 13 is connected via two pipeline sections to the feed 6 or the return 10 of the evaporator 5. The embodiment illustrated in FIG. 2 is therefore suitable in particular for the air conditioning of an IT environment, for example a data center, in which the housing 13 with the condenser 3 can be arranged outside the IT environment or the data center, for example on the roof of a container or of a building.

Furthermore, the embodiment according to FIG. 2 comprises a further shut-off member 12 in the return 10 of the evaporator 5. This can serve, after emptying of the evaporator 5 or of the components of the refrigerant circuit arranged in the internal air circuit 7 has taken place, to separate the components arranged in the internal air circuit 7 from the remaining refrigerant circuit, after which the compressor 2 could also be deactivated without risking refrigerant flowing back into the part of the refrigerant circuit arranged in the internal air circuit. The further shut-off member 12 can also be realized in the embodiment illustrated in FIG. 1.

The evaporator is configured in a housing 15 with an air inlet and an air outlet. In the housing 15, the internal air circuit is guided through the evaporator 5. In addition to the evaporator 5, the two shut-off members 11, 12 are also received in the housing 15. In an upper region of the housing 15, warm air from the interior 1001 of the IT environment 1000, for example from a data center, is sucked into the internal air circuit 7, conducted through the evaporator 5 and, in a lower region of the housing 15, introduced from the internal air circuit 7 or the housing 15 back into the interior 1001.

Deviating from the embodiment shown in FIG. 2, in the embodiment provided in FIG. 3, the compressor 2 is arranged in the internal air circuit. Analogously to the embodiment according to FIG. 2, the housing 13 for the condenser 3 can be an outdoor housing which is arranged, for example, outside a data center, for example on the roof of a data center. Furthermore, a collector 14 is arranged in the housing 13 of the condenser 3 in order to provide a receiving volume for refrigerant in the event of a leakage and when the feed 6 of the evaporator 5 is shut off by the shut-off member 4.

The features of the invention disclosed in the above description, in the drawings and in the claims can be essential for the realization of the invention both individually and in any desired combination.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

1-19. (canceled)

20. A method for operating a cooling device for the switchgear cabinet air conditioning or the air conditioning of an IT environment, for example a data centre, which comprises:
A. operating a refrigerating machine of the cooling device, the refrigerating machine comprising a refrigerant circuit with a compressor, a condenser, an expansion member and an evaporator;
B. detecting a leakage of the refrigerant circuit, in which refrigerant escapes from the refrigerant circuit;
C. shutting off a feed of the evaporator between the evaporator and the condenser; and
D. activating and/or maintaining the compressor activated, wherein a pipeline system of the evaporator, which is connected to the refrigerant circuit, is brought to a negative pressure with respect to an atmosphere in the interior of the switch cabinet housing or the IT environment.

21. The method according to claim 20, in which the activation and/or maintaining the compressor activated comprises the emptying of the refrigerant circuit in a line section of the refrigerant circuit which is arranged in an internal air circuit of the refrigeration appliance.

22. The method according to claim 20, in which refrigerant which is emptied from the line section of the refrigerant circuit arranged in the internal air circuit is transferred into a line section of the refrigerant circuit arranged in the external air circuit.

23. The method according to claim 22, in which the transfer of the refrigerant into a line section arranged in the external air circuit comprises the introduction of the refrigerant into a buffer store, preferably into an air-liquid heat exchanger of the condenser, particularly preferably into a line system of the air-liquid heat exchanger, with which the refrigerant is guided through the air-liquid heat exchanger in thermal contact with a plurality of fins of the air-liquid heat exchanger.

24. The method according to claim 20, in which, for shutting off the feed of the evaporator, the expansion member is transferred into a closed position which is completely impermeable or substantially impermeable to the refrigerant.

25. The method according to claim 20, in which the activation and/or maintaining the compressor activated comprises the raising of the rotational speed of the compressor, wherein the compressor is preferably operated at a maximum rotational speed.

26. The method according to claim 20, in which the shutting off of the feed of the evaporator between the evaporator and the condenser comprises the shutting off of a line section of the refrigerant circuit which is arranged in an external air circuit of the refrigeration appliance.

27. The method according to claim 20, in which, during the activation and/or maintaining the compressor activated, the compressor is kept activated either for a predetermined minimum duration and/or until a section of the refrigerant circuit, including the evaporator, arranged in the internal air circuit of the refrigeration appliance is completely or substantially completely emptied of the refrigerant.

28. The method according to claim 20, which, after the activation and/or maintaining the compressor activated, comprises the shutting off of a suction line of the compressor, via which suction line the compressor is connected to a return of the evaporator, and optionally the deactivation of the compressor.

29. An assembly of a switchgear cabinet housing or an IT environment, and a cooling device for the switchgear cabinet air conditioning, in particular for carrying out the method according to claim 20, in which the refrigeration appliance comprises a refrigerating machine with a refrigerant circuit, wherein the refrigerant circuit comprises a compressor, a condenser, an expansion member and an evaporator, wherein a feed of the evaporator comprises a shut-off member between the evaporator and the condenser, which shut-off member is configured to completely close the feed in the event of a leakage of the refrigerant circuit, wherein a pipeline system of the evaporator, which is connected to the refrigerant circuit, has a negative pressure with respect to the atmosphere in the interior of the switchgear cabinet housing or the IT environment.

30. The assembly according to claim 29, in which the shut-off member is the expansion member.

31. The assembly according to claim 29, in which the shut-off member is motor-driven and is controlled by a control unit which comprises a signal input for a refrigerant sensor.

32. The assembly according to claim 31, in which the refrigerant sensor is arranged in or on the cooling device, for example on an outer side of the cooling device facing a switch cabinet interior, in an air inlet opening or an air outlet opening of an internal air circuit of the cooling device or in the internal air circuit of the cooling device, wherein the refrigerant sensor is connected wirelessly or by wire to the signal input of the control unit.

33. The assembly according to claim 29, which comprises a further, preferably motor-driven shut-off member in a suction line of the compressor.

34. The assembly according to claim 29, in which at least the condenser, the compressor and at least one fan for acting on the condenser with air are accommodated separately from the evaporator in a separate housing which is connected via two pipeline sections to the feed and the return of the evaporator.

35. The assembly according to claim 34, in which the pipeline section connected to the feed of the evaporator comprises the shut-off member, wherein the shut-off member is preferably arranged closer to the evaporator than to the condenser along the pipeline section.

36. The assembly according to claim 34, in which the pipeline section connected to the return of the evaporator and the suction line of the compressor comprises a further shut-off member, wherein the further shut-off member is preferably arranged closer to the evaporator along the pipeline section.

37. The assembly according to claim 29, in which the compressor, the condenser, the expansion member, the evaporator and the at least one shut-off member are connected to one another via a pipeline system of the refrigerant circuit, wherein the pipeline system is conditioned with respect to its volume, in particular at least one of the pipeline cross-section and the pipeline length, such that the pipeline system is a buffer store for refrigerant compressed by the compressor in the event of a leakage when the feed of the evaporator is shut off.

38. The assembly according to claim 29, in which the compressor is arranged in the internal air circuit, in a housing in which at least the evaporator and the compressor are arranged, wherein the housing is preferably formed independently of a further housing in which the condenser and the external air circuit are arranged, and wherein the housing with the internal air circuit is arranged in an IT environment and the further housing with the external air circuit is arranged outside the IT environment.
